(19) United States
(12) Patent Application Publication
(10) Pub. No.: US 2011/0226306 A1
(43) Pub. Date: Sep. 22, 2011

(54) ADDITIVES FOR SOLAR CELL SEMICONDUCTORS

(75) Inventor: John C. Warner, Wilmington, MA (US)

(73) Assignees: OneSun, LLC, Sausalito, CA (US); Warner Babcock Institute for Green Chemistry, Wilmington, MA (US)

(21) Appl. No.: 13/030,055

(22) Filed: Feb. 17, 2011

Related U.S. Application Data
(60) Provisional application No. 61/305,861, filed on Feb. 18, 2010.
(60) Provisional application No. 61/305,899, filed on Feb. 18, 2010.
(60) Provisional application No. 61/305,908, filed on Feb. 18, 2010.
(60) Provisional application No. 61/305,911, filed on Feb. 18, 2010.

(51) Int. Cl. H01L 31/0352; H01L 31/02; H01L 31/0216; H01L 31/0248; H01L 31/042; H01L 31/0264

(52) U.S. Cl. 136/244; 136/261; 136/252; 136/263; 136/256; 257/43; 257/E31.004

(57) ABSTRACT

A dye-sensitized solar cell (“DSSC”) includes an anode, a cathode, a semiconductor layer, a dye covalently attached to the semiconductor layer, and an electrolyte, wherein the semiconductor layer includes a metal oxide and an organic or inorganic insulating component to facilitate forward transfer of electrons to the anode. The semiconductor additive or insulating component may include, for example, alpha aluminum oxide, gamma aluminum oxide, fumed silica, silica, diatomaceous earth, aluminum titanate, hydroxyapatite, calcium phosphate, iron titanate, and mixtures thereof.

### CROSS-REFERENCE TO RELATED APPLICATIONS

This application claims priority to U.S. Provisional Application No. 61/305,861, filed Feb. 18, 2010 and entitled, “SEMICONDUCTOR ADDITIVES FOR ELECTRON CHANNELING” [WBI 24.004]; U.S. Provisional Application No. 61/305,899, filed Feb. 18, 2010 and entitled, “COMPOSITION OF MATTER FOR SOLAR CELLS” [WBI 24.006]; U.S. Provisional Application No. 61/305,908, filed Feb. 18, 2010 and entitled, “NANONODULARITY FOR SEMICONDUCTORS IN SOLAR CELLS” [WBI 24.007]; and U.S. Provisional Application No. 61/305,911, filed Feb. 18, 2010 and entitled, “ROOM TEMPERATURE COALESCENCE OF METAL OXIDES FOR SOLAR CELLS” [WBI 24.008], the disclosures of which are hereby incorporated herein by reference.

Further, this application is related to Attorney Docket No. ONEP.P0025US entitled, “SYSTEMS AND METHODS FOR PREPARING COMPONENTS OF PHOTOVOLTAIC CELLS”; and Attorney Docket No. ONEP.P0030US entitled, “SEMICONDUCTOR COMPOSITIONS FOR DYE-SENSITIZED SOLAR CELLS,” both filed concurrently herewith and the disclosures of which are hereby incorporated herein by reference.

### TECHNICAL FIELD

The present disclosure generally relates to dye-sensitized solar cells (“DSSC”), and more particularly to semiconductor compositions and additives for improving conduction of photo-induced electrons through the semiconductor to improve conversion efficiency.

### BACKGROUND OF THE INVENTION

A solar cell, such as a DSSC, is a device that converts light into electricity through the photovoltaic effect. In a traditional DSSC, components may be stacked one on top of another. For example, an anode may be stacked on top of a semiconductor layer, which may be stacked on top of an electrolyte layer, which may be stacked on top of a cathode. The semiconductor is typically a layer of titanium dioxide onto which a photosensitive dye is adsorbed. In operation, light strikes the dye causing electrons to be released into the semiconductor. The electrons are transported through the semiconductor to the anode where they then exit the cell. The efficiency of the solar cell is affected by the ability of the electrons to traverse the semiconductor network and reach the anode. Not all electrons, however, complete the journey—some that stay in the semiconductor too long may, for example, recombine with the dye (referred to as back electron transfer). Electrons that do not make it to the anode do not contribute to the electrical current, thus reducing the efficiency of the solar cell. There is a need for a DSSC with improved efficiency, and particularly, an improved semiconductor that will better facilitate the transport of electrons to the anode.

### SUMMARY OF THE INVENTION

The present disclosure is directed to solar cells having improved conversion efficiency, including dye-sensitized solar cells, and compositions for semiconductors included in such solar cells. In one embodiment, the composition and structure of the semiconductor is controlled to enhance electron mobility by creating efficient pathways through the semiconductor. In one aspect, electron mobility can be enhanced by including insulating particles or other additives in the semi-conductor. Exemplary additives include alpha aluminum oxide, gamma aluminum oxide, fumed silica, silica, silicon oxide, diatomaceous earth, aluminum titanate, hydroxyapatite, calcium phosphate, iron titanate, or a mixture thereof. In another aspect, other properties of selected semiconductor additives, such as reflectivity and conduction band edge level, may further improve solar cell efficiency by, for example, facilitating electron mobility through the semiconductor, enhancing light reflectivity and/or light adsorption, increasing the probability of acceptance by the semiconductor of excited electrons, and reducing the risk of undesired reactions such as recombination of electrons with a dye coated on the semiconductor.

Various embodiments of the semiconductor compositions described in the present application may be incorporated into a dye-sensitized solar cell (DSSC). The DSSC may further include an anode, an electrolyte, and a cathode. In one aspect, the DSSC further includes a dye covalently bonded to the semiconductor. In another aspect, the dye includes an organic or organometallic dye. In another aspect, the DSSC includes a protective light-transparent top layer covering the DSSC.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### DESCRIPTION OF THE FIGURES

For a more complete understanding of the present disclosure, reference is now made to the following descriptions taken in conjunction with the accompanying drawings:

FIG. 1A is a schematic representation of the trajectory of a photoelectron in a traditional dye-sensitized solar cell;

FIG. 1B is a schematic representation of the trajectory of a photoelectron in an exemplary embodiment of a dye-sensitized solar cell with additives for electron channeling;

FIG. 1C shows an exemplary embodiment of a dye-sensitized solar cell with electron channeling;

FIG. 2 shows an exemplary embodiment of a dye-sensitized solar cell in a solar panel;

FIG. 3A shows an exemplary embodiment of a support structure for a solar panel;

FIG. 3B depicts a cross-sectional view of an exemplary embodiment of the flow of electrical energy between neighboring solar cells;

FIG. 4 shows an exemplary embodiment of a dye-sensitized solar cell incorporated into a solar-ready commercial rooftop;

FIG. 5 is a plot of the current-voltage character of a traditional dye-sensitized solar cell;

FIG. 6 is a plot of the current-voltage character of an exemplary embodiment of a dye-sensitized solar cell in which diatomaceous earth is added to the semiconductor;

FIG. 7 is a plot of the current-voltage character of an exemplary embodiment of a dye-sensitized solar cell in which fumed silica is added to the semiconductor;

FIG. 8 is a plot of the current-voltage character of an exemplary embodiment of a dye-sensitized solar cell in which gamma aluminum oxide is added to the semiconductor; and

FIG. 9 is a plot of the current-voltage character of an exemplary embodiment of a dye-sensitized solar cell in which aluminum titanate is added to the semiconductor.

### DETAILED DESCRIPTION OF THE INVENTION

In various embodiments of the present invention, the conversion efficiency of a DSSC is improved by including organic or inorganic insulating particles and/or other additives in the semiconductor matrix to facilitate the mobility of photo-induced electrons through the semiconductor to an anode. For example, the performance of the solar cell may be improved by selecting insulating particles or additives with the appropriate morphology and surface properties such as fumed silica, diatomaceous earth, and gamma aluminum oxide.

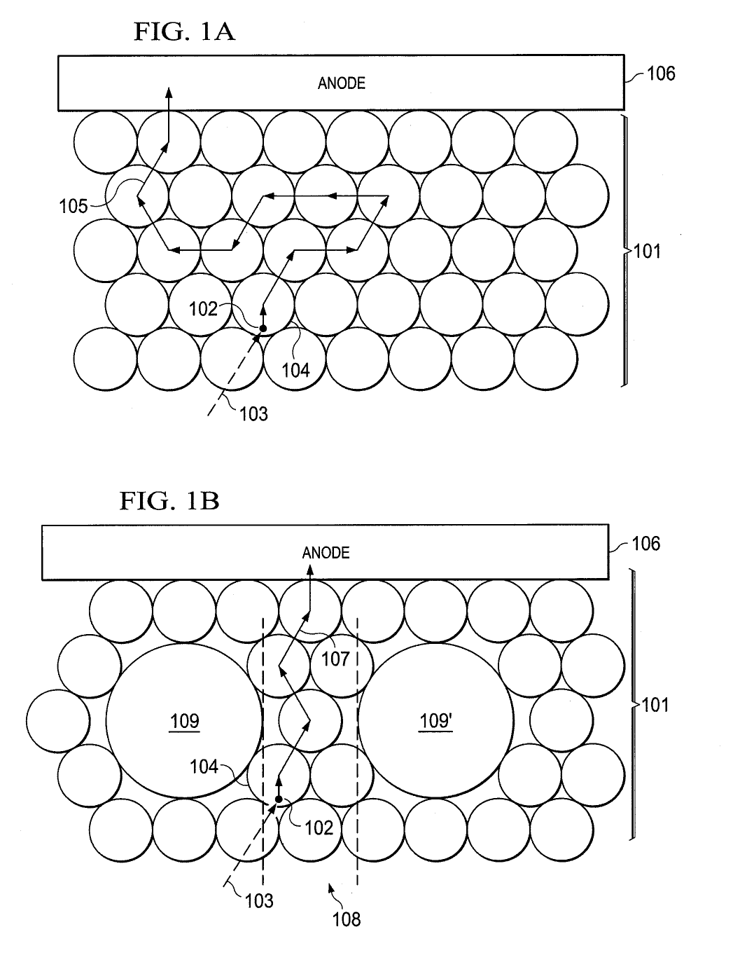

FIG. 1A is a schematic representation of the trajectory of an electron, shown as electron 102, in a single morphology semi-conductor 101. In the portion of a dye-sensitized solar cell shown in FIG. 1A, an electron 102 is produced when incident light 103 interacts with a dye adsorbed on the surface of a semiconductor particle 104, exciting electrons. An excited electron, such as electron 102, is thus injected into the semiconductor network on which the dye is adsorbed and travels along an electron pathway 105 to reach anode 106. Without guidance toward anode 106, electron 102 may follow a long, indirect, and/or inefficient electron pathway 105. The longer an electron, such as electron 102, remains in the semiconductor, the greater the risk of alternative reactions occurring that inhibit electron flow toward the anode and reduce solar cell efficiency. For example, electrons injected into the semiconductor may recombine with the oxidized dye (also referred to as back electron transfer).

It is believed that the mobility of electrons in a semiconductor may be enhanced, and thus, the efficiency of a solar cell enhanced, by controlling the composition and morphology of the semiconductor. In one embodiment, organic or inorganic insulating compounds are added to the semiconductor to create areas of photoelectron exclusion. As a result, an electron's passage, such as electron passage 108 in FIG. 1B, through the semiconductor is more direct and efficient. This exclusion zone effect is demonstrated in FIG. 1B.

FIG. 1B, in comparison to FIG. 1A, is a schematic representation of the trajectory of an electron in an exemplary embodiment of the present disclosure. In FIG. 1B, insulating particles 109, 109′ are mixed with semiconductor particles, such as semiconductor particle 104. Semiconductor particles 104 may be, for example, nanoparticles or a nanonodular network of titanium dioxide, and semiconductor 101 may be used, for example, in the form a nanoparticle substrate. Electron flow is restricted or occluded at insulating particles 109, 109′, creating a neck or electron passage 108 in the semiconductor matrix through which electron 102 passes following path 107. Path 107 through electron passage 108 is more direct and efficient than electron pathway 105 depicted in FIG. 1A. Further, by facilitating movement of electrons toward the anode, a more efficient solar cell is produced. Only one path, electron pathway, and electron are shown for illustrative purposes. One of ordinary skill in the art appreciates that there may be a plurality of pathways through the semiconductor and a plurality of electrons traversing such pathways at any given time during operation of the solar cell. Further, the pathway traversed by any particular electron injected into the semiconductor may depend on a number of factors, for example, proximity of the point of origin to a particular pathway.

To complete the solar cell described in FIG. 1B, a stacked DSSC as illustrated in FIG. 1C is constructed. The DSSC illustrated in FIG. 1C includes superstrate 114 interfaced with anode portions 106, 106′, 106″ having open areas 113, 113′ (for receiving incident light 103), electrolyte 110 (for regenerating semiconductor 101) interfaced with semiconductor 101, cathode 111 (for regenerating electrolyte 110) interfaced with electrolyte 110, and substrate 112 interfaced with cathode 111. In various embodiments, superstrate 114 may be clear or transparent to allow light to pass through and may include one or more of the following materials: poly (methyl methacrylate) (also called PMMA) and poly(ethylene terephthalate) (also called PET). Substrate 112 may include, for example, PET. Further, anode 106, 106′, and 106″ and cathode 111 may be made of material such as silver, copper, aluminum, nickel, gold, platinum, carbon, conductive polymers, carbon nanotubes, graphene, and combinations thereof. A photo-sensitive dye may be organic or organometallic dye impregnated or adsorbed on the semiconductor material. Exemplary dyes include ruthenium bipyridyl dicarboxylate dye (also called N3) and other chromophores containing carboxylic acids or functional groups capable of binding to titanium dioxide. Further, an exemplary electrolyte includes a liquid iodide-triiodide (I₃⁻/I⁻) redox couple or other suitable electrolytes capable of regenerating the photo-oxidized dye.

As illustrated in FIG. 1B and the examples contained herein, controlling the composition and morphology of the semiconductor enhances solar cell performance. In traditional dye-sensitized solar cells, the semiconductor is composed of a single metal oxide, commonly titanium dioxide. Titanium dioxide may take the form of nano-scale particles, larger micron scale particles, or as dispersed nanoparticles formed in situ from a titanium solution. To prepare a traditional semiconductor known in the art, titanium dioxide nano-scale particles are sintered at high temperatures of about 450° C. to 500° C. In contrast, exemplary embodiments of a semiconductor according to the present disclosure may be prepared via low temperature sintering at about 100° C. to 150° C. Although the crystalline structure formed as a result of low temperature sintering is different than that formed at high temperatures, the low temperature process does not interfere with the formation of electron pathways or “necks” (such as electron pathway 108 shown and described at FIG. 1B) between nanoparticles or nanonodules of titanium dioxide, such pathways facilitating movement of electrons toward the anode. Further details on nanonodular and low-temperature semiconductor formation are provided in patent applications listed above, filed concurrently herewith, and entitled, “SEMICONDUCTOR COMPOSITIONS FOR DYE-SENSITIZED SOLAR CELLS” (Attorney Docket No. ONEP.P0030US) and “SYSTEMS AND METHODS FOR PREPARING COMPONENTS OF PHOTOVOLTAIC CELLS” (Attorney Docket No. ONEP.P0025US), the disclosures of which are incorporated herein by reference.

In one embodiment of the present invention, an organic or inorganic insulating compound is added to the semiconductor to create a mixed morphology semiconductor, and thus, facilitate electron mobility through the exclusion zone effect illustrated in FIG. 1B. Exemplary insulating compounds include nonconductive metal oxides, organic salts, and combinations thereof. More particularly, exemplary insulating compounds include fumed silica, diatomaceous earth, gamma aluminum oxide, and combinations thereof.

The appropriate amount of organic or inorganic insulator to add to the titanium-dioxide based semiconductor depends on several factors, for example, the presence and amount of other semiconductor components (for example, linking molecules for nanonodular network formation), particle identity, particle size, particle shape, and particle size distribution. In various embodiments, the organic or inorganic insulator is at least 3%, at least 5%, at least 8%, at least 10%, at least 15%, or at least 20% by weight of the semiconductor. A solar cell having organic or inorganic insulators and/or mixed morphology may operate with greater efficiency than the same solar cell with a semiconductor having only a single morphology, such as a single morphology titanium dioxide.

Optimizing electron mobility through semiconductor composition control may include consideration of a variety of other factors. For example, an insulator may be selected because the conduction band edge is at a level suited for accepting electrons from the dye. Materials exhibiting appropriate conduction band edge level include aluminum titanate, hydroxyapatite, calcium phosphate, and iron titanate. Further, for example, an insulator may be selected because it has light reflecting properties that increase the probability of light contact with dye molecules, which then may lead to increased light absorption. Materials exhibiting beneficial light reflecting properties include alpha alumina and silicon oxide in the form of standard powders or in the form of diatomaceous earth.

In various embodiments, the insulator or additive may be incorporated into traditional titanium dioxide thin films or with a thin film dye-sensitized solar cell. For example, the organic or inorganic insulator may be mixed into a titanium dioxide-based slurry and then the slurry deposited as a mixture on a solid support or substrate.

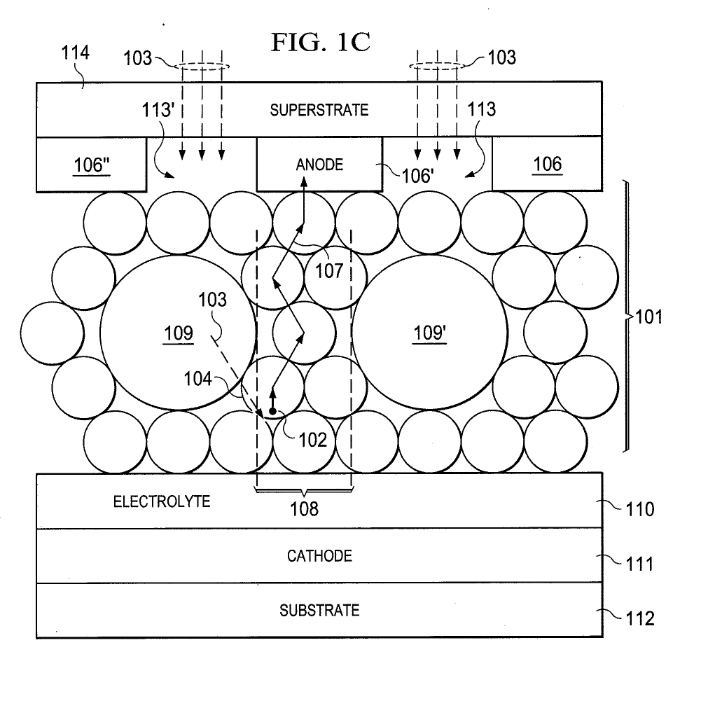

Further, exemplary embodiments of a dye-sensitized solar cell with organic or inorganic additives as disclosed herein (such as described in FIGS. 1B and 1C), may be incorporated into a network to produce energy. Exemplary embodiments of a network of solar cells having organic or inorganic additives are illustrated in FIGS. 2, 3A, 3B, and 4.

FIG. 2 illustrates a solar panel 20 including an arrangement of solar cells 204 within modules 203. In the illustrated embodiment, solar cells 204 and modules 203 have a substantially planar top surface 207 for receiving incident light 208, 209, 210 at various angles. Top surface 207 lie in the same plane as top surfaces of neighboring modules to form a solar panel 20 that has a substantially horizontal orientation.

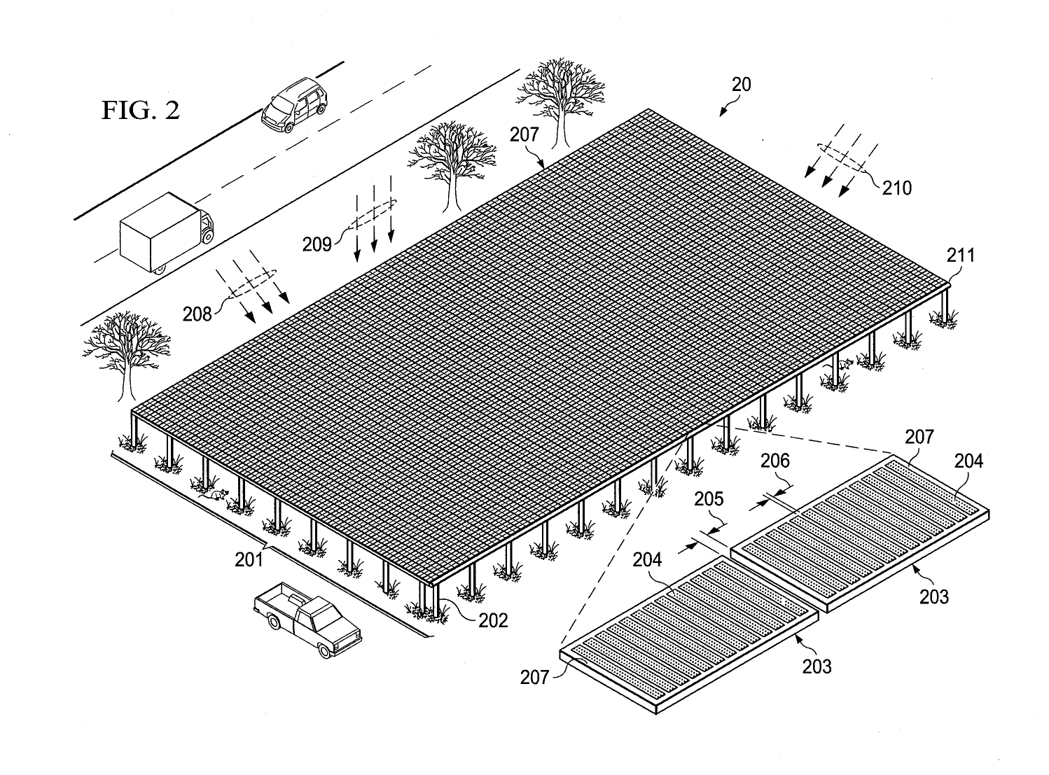

Each solar cell 204 and module 203 (and solar cells 303-1 to 303-n and modules 301, discussed infra) may be of various shapes, dimensions, or patterns, and of uniform or non-uniform shape, dimension, or pattern with respect to other modules or solar cells. In the illustrated embodiment, modules 203 and solar cells 204 are rectangular and parallel with respect to other solar cells in the same module. In one embodiment, each module 203 has a length of about 50 inches and a width of about 30 inches, and each solar cell 204 has a width equal to or less than 30 inches and a length of about 1 3/16 inches. Each solar cell 204 may be electrically connected in series to a neighboring solar cell 204 (see, for example, FIG. 3B). Further, solar cells 204 may be separated by a predetermined distance 206 from neighboring solar cells, and modules 203 may be separated by predetermined distances 205 from neighboring modules. In the space between solar cells 204, such as predetermined distance 205, a bus bar may be situated and electrically connected to solar cells 204 to aid in capturing electrical energy.

In one embodiment, solar panel 20 may be elevated off the ground or other surface with support structure 201. Support structure 201 may include a frame, where the frame is formed of beams, such as beam 211. Support cables, as illustrated in FIG. 3A, may also be used to support or stabilize modules 203. Such support cables may be attached to a frame, such as formed from beams 211, or directly to posts 202. Further, in the illustrated embodiment, posts 202 are used to support the frame and solar panel 20. In one embodiment, posts 202 do not extend above the plane of module surface 207, thereby eliminating potential shading or blocking of incident light. Further, the height of elevation for solar panel 20 may be selected to permit human, vehicular, or robotic access to interior modules 203 for cleaning, maintenance, or replacement, to allow maintenance of grounds beneath solar panel 20, or to allow wild life to roam freely without interfering with solar panel 20 (and minimally interfering with the ability of wild life to freely roam). The energy produced by modules 203 may be used locally, for example to power a local device or structure (not shown), or optionally transported along connected electrical lines (not shown) to a power distribution network for distribution and use elsewhere, such as with a utility grid.

FIG. 3A illustrates an exemplary embodiment of a solar panel support structure 30a. In the exemplary embodiment illustrated in FIG. 3A, array of modules 301, including plurality of solar cells 303-1 to 303-n, are held in position to receive incident light 308 by support structure 30a. In this embodiment, support structure 30a includes tensioned wires or support cables 305. Support cables 305 may, as illustrated, run coextensive with the horizontal plane (i.e., module surfaces 304) of modules 301. Support cables 305 are supported by posts 307. Posts 307 and support cables 305 also provide elevation to array of modules 301 to achieve, for example, those advantages of elevation described for FIG. 2. Further, modules 301 are connected to support cables 305 by one or more support connectors 306.

FIGS. 3A and 3B illustrate an exemplary embodiment of the flow of electricity between modules and solar cells, respectively. In the embodiment illustrated in FIG. 3A, modules 301 are connected in series such that the output of one module 301 is the input of an adjacent module via electrical connectors 302a and electrical cables 302b. Electrical energy produced at modules 301 follows path 309 for collection and/or distribution to a structure, network, or other system. In the embodiment illustrated in FIG. 3B, the flow of electricity within module 301 and among solar cells 303-1 to 303-n is shown. Depicted is a cross-sectional view 30b of neighboring solar cells 303-1 and 303-2 receiving incident light 308 at solar cell surfaces 317-1 and 317-2, respectively. Solar cells 303-1 and 303-2 each respectively include superstrates 310-1 and 310-2, anodes 312-1 and 312-2, semiconductors 314-1 and 314-2, electrolytes 315-1 and 315-2, cathodes 313-1 and 313-2, and substrates 311-1 and 311-2. Electrical path 316 demonstrates the flow of electrical energy from anode 312-1 of solar cell 303-1 to cathode 313-2 of solar cell 303-2. This transfer of electricity continues to the next solar cell of module 301 until reaching solar cell 303-n, and then exiting the module via electrical connector 302a and electrical cable 302b (illustrated in FIG. 3A).

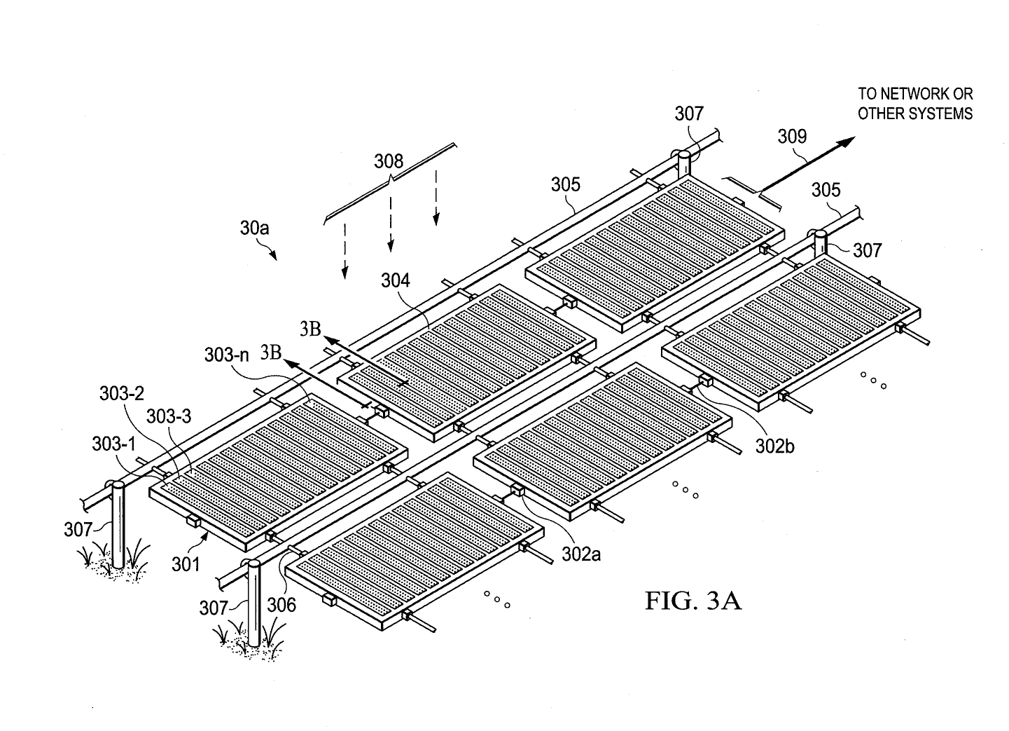

FIG. 4 illustrates another exemplary embodiment of a dye-sensitized solar cell incorporated into a network to produce energy. In system 40, modules 403 are incorporated into a solar-ready commercial rooftop 404 of commercial building 401. Although a substantially rectangular commercial rooftop 404 is shown, those of skill in the art will appreciate that the rooftop may be a variety of shapes or dimensions, of non-uniform height, or may be incorporated into non-commercial rooftops. In exemplary system 40, each module 403 is spaced a predetermined distance from another module, and several modules are placed in an array to form panels 402. Each panel 402 of this embodiment has a substantially horizontal orientation for receiving incident light on the surface of modules 403. Modules 403 may be each electrically connected to one another (for example, as described with reference to FIGS. 2, 3A, and 3B) and/or building's 401 electrical system by electrical connectors or terminal wires (not shown) and provide power for operations contained within building 401. Surplus power may optionally be directed to other local structures or to a power distribution network for distribution and use at other locations or facilities. The roof of the building may provide support for modules 403 or, alternatively, posts and tensioned wires or cables, such as described with reference to FIGS. 2 and 3A, may be incorporated to provide elevation to modules 403 and/or panels 402.

### EXAMPLES

Exemplary embodiments of a DSSC with additives according to the present invention are now presented and compared to a traditional DSSC having no such additives.

### Example 1

Photovoltaic device with diatomaceous earth added to the semiconductor. Two dye-sensitized solar cells were assembled. First, a traditional dye-sensitized solar cell, i.e., a Gratzel cell, was constructed. The Gratzel cell was made by first constructing a top portion by depositing fluorine-doped tin dioxide (SnO₂F) on a transparent plate. A thin layer of titanium dioxide (TiO₂) was deposited on the transparent plate having a conductive coating. The TiO₂ coated plate was then dipped into a photosensitized dye, ruthenium-polypyridine dye, in solution. A thin layer of the dye bonded to the surface of the titanium dioxide. A bottom portion of the Gratzel cell was made from a conductive plate coated with platinum metal. The top portion and the bottom portion were then joined and sealed. The electrolyte, an iodide-triiodide redox couple, was then inserted between the top and bottom portions of the Gratzel cell.

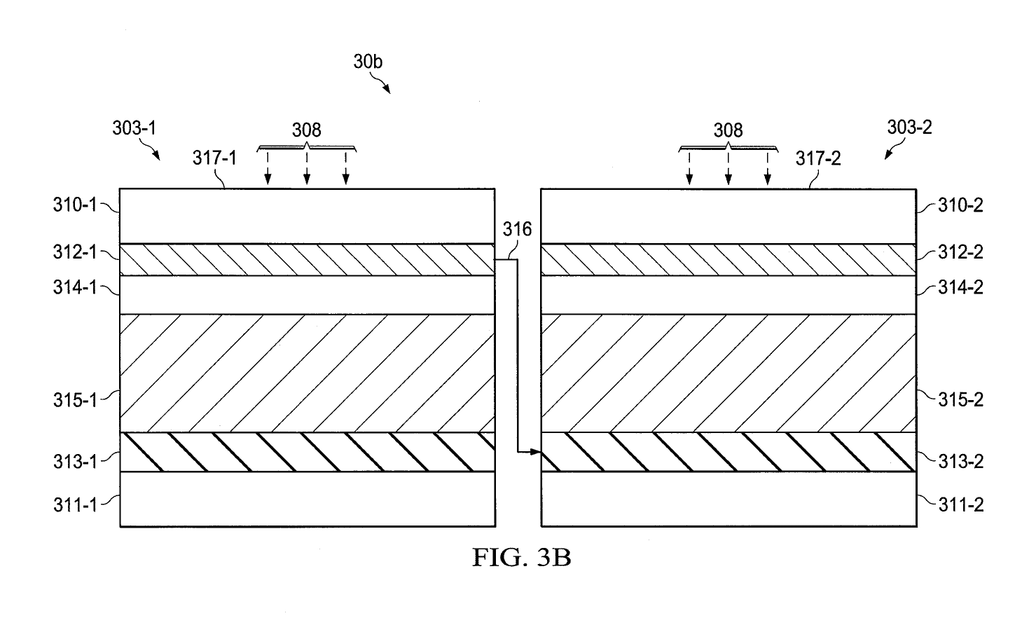

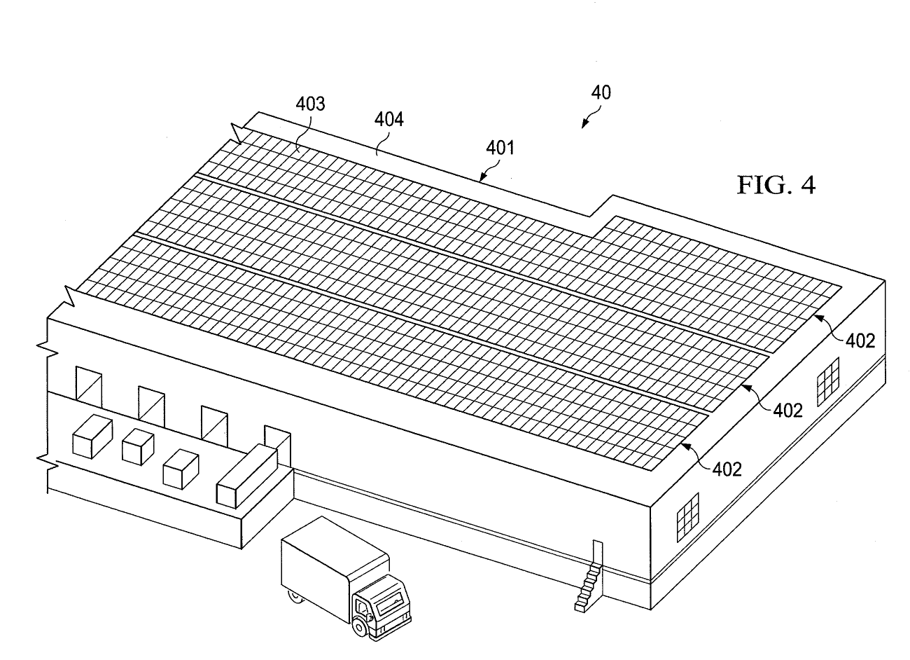

Second, an experimental dye-sensitized solar cell was constructed in the same manneras the Gratzel cell, except that 8% by weight diatomaceous earth was added to the titanium dioxide slurry. Diatomaceous earth is known to reflectively scatter light and also has a larger surface area per unit of weight than the titanium dioxide. The resulting current-voltage character of both cells are presented in FIGS. 5 and 6, respectively. FIG. 5 is a plot of the current-voltage character of a dye-sensitized cell without diatomaceous earth. FIG. 6 is a plot of the current-voltage character of a dye sensitized cell with 8% by weight diatomaceous earth added to a titanium dioxide slurry. As shown in FIG. 5, the efficiency of the solar cell without the additive is 3.74%. As shown in FIG. 6, the efficiency of the same solar cell with the semiconductor additive, diatomaceous earth, is 4.13%. Thus, adding diatomaceous earth to the titanium dioxide particles of the semiconductor resulted in a 10% increase in efficiency.

### Example 2

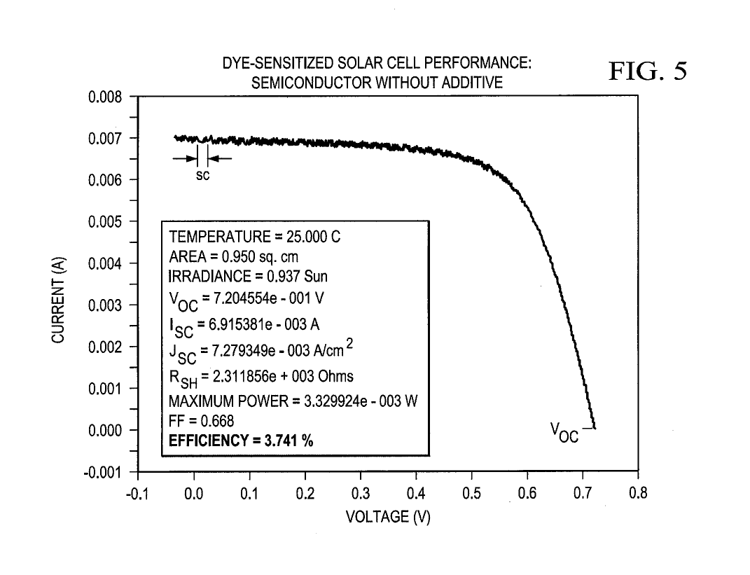

DSSC with fumed silica added to the semiconductor. An experimental dye-sensitized solar cell was constructed in the same manner as the solar cell represented by FIG. 5, except that 8% by weight fumed silica was added to the titanium dioxide slurry. The current-voltage character of the experimental cell is presented in FIG. 7. As shown in FIG. 5, the efficiency of the cell without an additive is 3.74%. As shown in FIG. 7, the efficiency of the cell with fumed silica added to the semiconductor is 4.21%. Thus, adding fumed silica to the titanium dioxide particles of the semiconductor resulted in a 12.5% increase in efficiency.

### Example 3

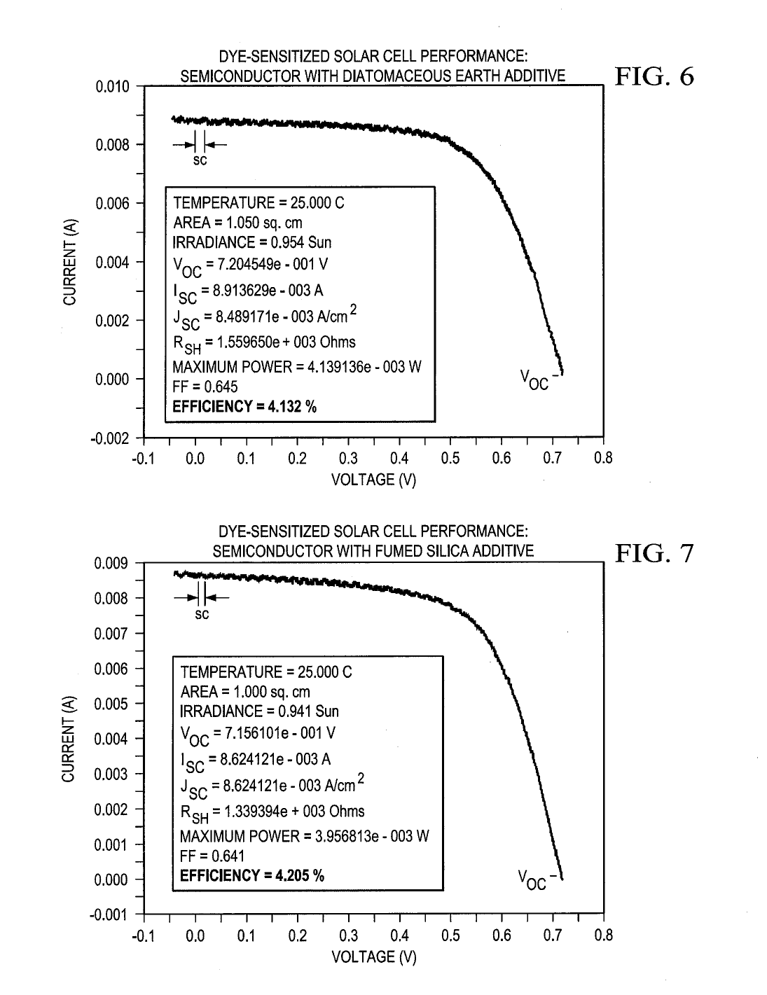

DSSC with gamma aluminum oxide added to the semiconductor. An experimental dye-sensitized solar cell was constructed in the same manner as the solar cell represented by FIG. 5, except that 8% by weight gamma aluminum oxide was added to the titanium dioxide slurry. Gamma aluminum oxide is an insulator, and due to its high conduction band edge, cannot efficiently absorb photo-induced electrons generated by the dye. However, added at the optimal level, the gains in light adsorption attributable to higher surface area outweigh impedance attributable to the presence of dispersed insulating particles. The current-voltage character of the experimental cell is presented in FIG. 8. As shown in FIG. 5, the efficiency of the cell without an additive is 3.74%. As shown in FIG. 8, the efficiency of the cell with gamma aluminum oxide added to the semiconductor is 4.45%. Thus, adding gamma aluminum oxide to the titanium dioxide particles of the semiconductor results in a 19% increase in efficiency.

### Example 4

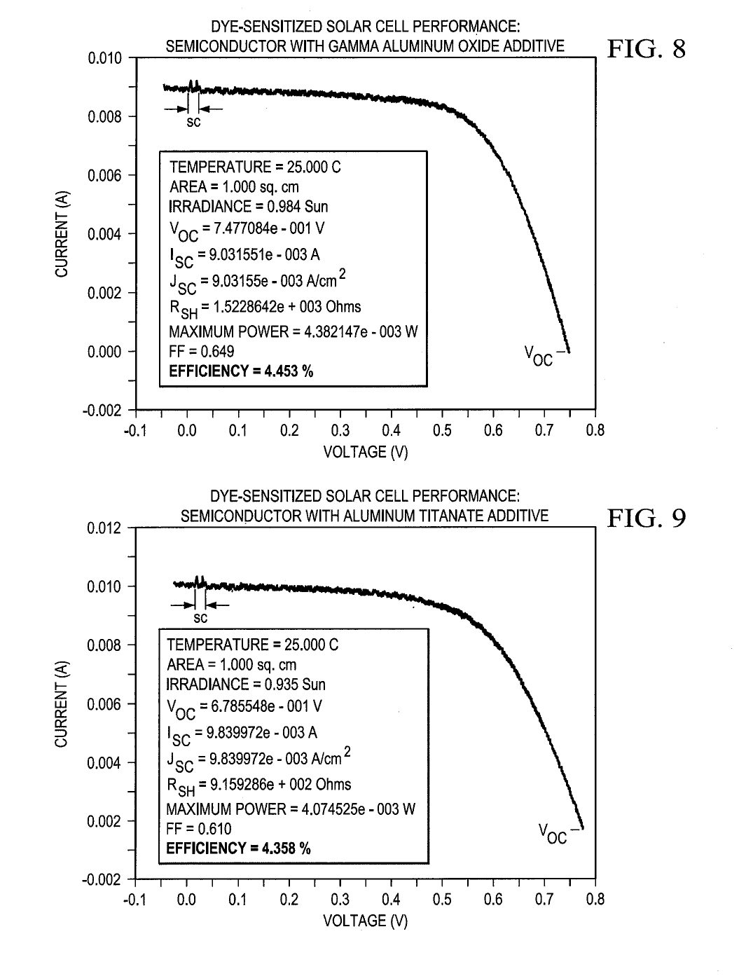

DSSC with aluminum titanate added to the semiconductor. Aluminum titanate has a conduction band edge level that permits photoelectrons to be accepted from the dye. To illustrate its effect as an additive, an experimental solar cell was constructed in the same manner as the solar cell represented by FIG. 5, except that 5% by weight aluminum titanate was added to the titanium dioxide slurry. The current-voltage character of the experimental cell is presented in FIG. 9. As shown in FIG. 9, the efficiency of the cell with aluminum titanate added to the semiconductor is 4.36%. Thus, adding aluminum titanate to the titanium dioxide particles of the semiconductor results in a 16% increase in efficiency.

Accordingly, the conversion efficiency of light, such as sunlight, to electricity, using a DSSC can be improved by including insulating particles or other additives in the semiconductor layer.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor for use in a dye-sensitized solar cell (DSSC), said semiconductor comprising:
a metal oxide; and
at least one insulating component, said insulating component forming a pathway for an electron through the metal oxide to the anode.

2. The semiconductor of claim 1 wherein the pathway yields greater conversion efficiency than the metal oxide without the insulating component.

3. The semiconductor of claim 1 wherein the inorganic insulating component is at least one of the compounds selected from the group consisting of: fumed silica, diatomaceous earth, gamma aluminum oxide, and a combination thereof.

4. The semiconductor of claim 1 wherein the metal oxide comprises titanium dioxide.

5. The semiconductor of claim 1 wherein the metal oxide comprises a nanoparticle substrate of titanium dioxide.

6. The semiconductor of claim 1 wherein the morphology of the metal oxide is different than the morphology of the insulating component.

7. The semiconductor of claim 1 wherein the insulating component is about 3% to about 15% by weight of the semiconductor.

8. A dye-sensitized solar cell (DSSC) comprising:
an anode, an electrolyte, and a semiconductor, said semiconductor comprising:
an insulating compound selected from the group consisting of fumed silica, diatomaceous earth, gamma aluminum oxide, and a combination thereof;
wherein the additive forms a pathway for excited electrons through said metal oxide layer to the anode.

9. The dye-sensitized solar cell of claim 8 further comprising a dye covalently bonded to the semiconductor.

10. The dye-sensitized solar cell of claim 9 wherein the dye comprises an organic dye.

11. The dye-sensitized solar cell of claim 8 further comprising a protective light-transparent top layer covering the DSSC.

12. A dye-sensitized solar cell (DSSC) comprising:
an anode, a cathode, a semiconductor, a dye covalently bonded to the semiconductor, and an electrolyte;
wherein the semiconductor comprises: a metal oxide and an additive, said additive selected from the group consisting of alpha aluminum oxide, gamma aluminum oxide, fumed silica, silica, silicon oxide, diatomaceous earth, aluminum titanate, hydroxyapatite, calcium phosphate, iron titanate, or a mixture thereof; and
wherein the additive is in a formulation to cause the DSSC to operate with greater conversion efficiency than the DSSC without the additive in the semiconductor.

13. The dye-sensitized solar cell of claim 12 wherein the metal oxide comprises titanium dioxide.

14. The dye-sensitized solar cell of claim 12 wherein the metal oxide comprises a nanoparticle substrate of titanium dioxide.

15. The dye-sensitized solar cell of claim 12 wherein the dye comprises an organic dye.

16. The dye-sensitized solar cell of claim 12 wherein the morphology of the metal oxide is different than the morphology of the additive.

17. The dye-sensitized solar cell of claim 12 wherein a surface area by weight of the insulating component is greater than a surface area by weight of the titanium dioxide, and wherein light absorption of the semiconductor with the additive is higher than the light absorption efficiency of the semiconductor without the additive.

18. The dye-sensitized solar cell of claim 12 wherein the additive is about 3% to 20% by weight of the semiconductor.

19. The dye-sensitized solar cell of claim 12 further comprising a protective light-transparent top layer covering the DSSC.

20. A method of converting solar energy, said method comprising:
exposing a solar cell to light and thereby producing electrical energy, said solar cell comprising:
a metal oxide; and at least one insulating component, said insulating component forming a pathway for an electron through the metal oxide to the anode.

21. A method of claim 20 further comprising electrically connecting an array of said solar cells to form a network of said solar cells for producing electrical energy for a utility grid.
